(19) United States
(12) Patent Application Publication
(10) Pub. No.: US 2026/0206463 A1
(43) Pub. Date: Jul. 16, 2026

(54) DISPLAY PANEL AND ELECTRONIC DEVICE INCLUDING THE SAME

(71) Applicant: Samsung Display Co., Ltd., Yongin-si (KR)

(72) Inventors: JAEHEUNG HA, Yongin-si (KR); JONGWOO KIM, Yongin-si (KR); YONGCHAN JU, Yongin-si (KR)

(21) Appl. No.: 19/380,731

(22) Filed: Nov. 5, 2025

(30) Foreign Application Priority Data
Jan. 13, 2025 (KR) 10-2025-0004944

(51) Int. Cl. H10K 59/80; H10K 59/12; H10K 59/121; H10K 59/122

(52) U.S. Cl. CPC H10K 59/873; H10K 59/1201; H10K 59/1213; H10K 59/122

(57) ABSTRACT

A display panel including: a base layer; a circuit element layer including at least one inorganic layer on the base layer, at least one intermediate insulating layer on the at least one inorganic layer, and a transistor; a light emitting element comprising a first electrode electrically connected to the transistor, an emissive layer, and a second electrode on the emissive layer; a pixel defining layer on the circuit element layer and defining a light emitting opening exposing the first electrode; a barrier pattern including one portion that protrudes above the pixel defining layer, and contacting the at least one inorganic layer through an opening passing through the at least one intermediate insulating layer and the pixel defining layer; and a thin film encapsulation layer including a first inorganic encapsulation layer contacting the barrier pattern and overlapping the light emitting element, a second inorganic encapsulation layer.

### CROSS-REFERENCE TO RELATED APPLICATION

This application claims priority to and the benefit of Korean Patent Application No. 10-2025-0004944, filed on Jan. 13, 2025, in the Korean Intellectual Property Office, the entire disclosure of which is incorporated by reference herein.

### BACKGROUND

The present disclosure relates to a display panel and an electronic device including the same, and more particularly, relates to a display panel in which the thickness of a thin film encapsulation layer is improved and an electronic device including the same.

A display device, such as a television, a monitor, a smart phone, a tablet computer, and/or the like, which provides an image to a user includes a display panel that displays an image. Various display panels, such as a liquid crystal display panel, an organic light emitting display panel, an electro wetting display panel, an electrophoretic display panel, and/or the like, are being developed.

An organic light emitting diode (OLED), which is a light emitting element made of organic materials, can be used to implement a thin and flexible display. In order to extend the lifetime of the OLED element and protect the OLED element from an external environment, a thin film encapsulation (TFE) among various structures included in the OLED is being developed as a thin encapsulation structure formed by alternately stacking an organic layer and an inorganic layer.

### SUMMARY

Embodiments of the present disclosure provide a display panel for increasing flexibility while maintaining sealing characteristics.

Embodiments of the present disclosure provide an electronic device including the display panel.

According to one or more embodiments, a display panel includes a base layer, a circuit element layer including at least one inorganic layer on the base layer, at least one intermediate insulating layer on the at least one inorganic layer, and a transistor, a light emitting element including a first electrode electrically connected to the transistor, an emissive layer, and a second electrode on the emissive layer, a pixel defining layer that is on the circuit element layer and that includes a light emitting opening defined therein to expose the first electrode, a barrier pattern that includes one portion that protrudes above the pixel defining layer and makes contact with the at least one inorganic layer through an opening that passes through the at least one intermediate insulating layer and the pixel defining layer, and a thin film encapsulation layer including a first inorganic encapsulation layer that makes contact with the barrier pattern and covers the light emitting element, a second inorganic encapsulation layer, and an organic pattern between the first inorganic encapsulation layer and the second inorganic encapsulation layer to overlap the light emitting opening.

The display panel may include an emissive area corresponding to the light emitting opening and a non-emissive area corresponding to the pixel defining layer, and the first inorganic encapsulation layer and the second inorganic encapsulation layer may make contact with each other in the non-emissive area.

An area where the first inorganic encapsulation layer and the second inorganic encapsulation layer are in contact with each other may be located on the barrier pattern.

The one portion of the barrier pattern that protrudes above the pixel defining layer may be in contact with the first inorganic encapsulation layer.

The light emitting element may include a first light emitting element and a second light emitting element.

A second electrode of the first light emitting element and a second electrode of the second light emitting element may be separated from each other by the barrier pattern.

The barrier pattern may include a first metal portion inserted into the opening and a second metal portion that protrudes from the pixel defining layer, and the second metal portion may have a greater width than the first metal portion and may protrude from the first metal portion on a plane.

The first metal portion and the second metal portion may have different etch rates.

The second metal portion may include a central portion that overlaps the first metal portion in a thickness direction of the display panel, a first side portion that does not overlap the first metal portion in the thickness direction of the display panel, and a second side portion that does not overlap the first metal portion in the thickness direction of the display panel, and the central portion may be between the first side portion and the second side portion.

The display panel may include a display area including the emissive area and the non-emissive area and a non-display area outside the display area, and the first inorganic encapsulation layer and the second inorganic encapsulation layer may be in contact with each other in the non-display area.

The barrier pattern may have a closed-loop shape surrounding the light emitting element on a plane.

The light emitting element may include a plurality of light emitting elements, and the barrier pattern may surround the plurality of light emitting elements in a closed-loop shape on a plane.

The display area may include a first display area and a second display area, and a plurality of light emitting elements may be in each of the first display area and the second display area. The barrier pattern may include a first barrier pattern and a second barrier pattern. The first barrier pattern may surround the first display area, and the second barrier pattern may surround the second display area.

The barrier pattern having the closed-loop shape may block infiltration of oxygen and moisture into an emissive area corresponding to the light emitting opening.

The transistor may include a semiconductor pattern and a gate electrode over the semiconductor pattern. The at least one inorganic layer may include a barrier layer that is between the semiconductor pattern and the base layer and that includes silicon nitride. The barrier pattern may be in contact with the barrier layer.

The at least one inorganic layer may further include one or more intermediate inorganic layers on the barrier layer. An intermediate inorganic layer from among the one or more intermediate inorganic layers may be located between the semiconductor pattern and the gate electrode, and another one of the intermediate inorganic layers may be on the gate electrode. The opening may pass through the one or more intermediate inorganic layers.

The light emitting element may include a first light emitting element and a second light emitting element.

The organic pattern may include a first organic pattern that overlaps the first light emitting element and a second organic pattern that overlaps the second light emitting element, and the first organic pattern and the second organic pattern may be spaced from each other.

The barrier pattern may be located between the first organic pattern and the second organic pattern, and the first inorganic encapsulation layer and the second inorganic encapsulation layer may be in contact with each other on the barrier pattern.

According to one or more embodiments, a display panel includes a base layer, a circuit element layer including a semiconductor pattern over the base layer, a barrier layer between the base layer and the semiconductor pattern, at least one intermediate insulating layer on the barrier layer, and a transistor, a light emitting element including a first electrode electrically connected to the transistor, an emissive layer, and a second electrode on the emissive layer, a pixel defining layer that is on the circuit element layer and that includes a light emitting opening defined therein to expose the first electrode, and a thin film encapsulation layer including a first inorganic encapsulation layer in contact with the pixel defining layer and covering the light emitting element, a second inorganic encapsulation layer, and an organic pattern between the first inorganic encapsulation layer and the second inorganic encapsulation layer overlapping the light emitting opening. On a plane, the thin film encapsulation layer includes a first area where the first inorganic encapsulation layer and the second inorganic encapsulation layer are in contact with each other and a second area where the organic pattern is located.

The display panel may further include a barrier pattern including one portion that protrudes above the pixel defining layer and in contact with the first inorganic encapsulation layer, and the barrier pattern may be in contact with at least one inorganic layer through an opening that passes through the at least one intermediate insulating layer and the pixel defining layer. The first area may be located on the barrier pattern.

The barrier pattern may have a closed-loop shape surrounding the light emitting element on a plane.

The barrier pattern may include a first metal portion inserted into the opening and a second metal portion that protrudes from the pixel defining layer. The second metal portion may have a width that is greater than a width of the first metal portion and may protrude from the first metal portion on a plane. The barrier pattern may have a T-shape on a cross-section.

According to one or more embodiments, an electronic device includes a display device including a display panel and a processor that controls the display device. The display panel includes a base layer, a circuit element layer including at least one inorganic layer on the base layer and at least one intermediate insulating layer on the at least one inorganic layer, a light emitting element including a first electrode, an emissive layer, and a second electrode on the emissive layer, a pixel defining layer that is on the circuit element layer and that includes a light emitting opening defined therein to expose the first electrode, a barrier pattern that includes one portion that protrudes above the pixel defining layer and makes contact with the at least one inorganic layer through an opening that passes through the at least one intermediate insulating layer and the pixel defining layer, and a thin film encapsulation layer including a first inorganic encapsulation layer that is in contact with the barrier pattern and covers the light emitting element, a second inorganic encapsulation layer, and an organic pattern between the first inorganic encapsulation layer and the second inorganic encapsulation layer overlapping the light emitting opening.

The electronic device may be one of a smart watch, a vehicle display device, a tablet computer, AR glasses, and a smart phone.

### BRIEF DESCRIPTION OF THE DRAWINGS

The above and other aspects and features of the present disclosure will become apparent by describing in detail embodiments thereof with reference to the accompanying drawings.

FIG. 1A is a block diagram of an electronic device according to one or more embodiments of the present disclosure.

FIGS. 1B-1D are perspective views of the electronic device according to one or more embodiments of the present disclosure.

FIG. 2 is a perspective view of a display device according to one or more embodiments of the present disclosure.

FIG. 3 is a sectional view of the display device illustrated in FIG. 2.

FIG. 4 is a plan view of a display panel illustrated in FIG. 3.

FIG. 5 is an enlarged plan view of a portion of a display area of the display panel according to one or more embodiments of the present disclosure.

FIG. 6 is a sectional view taken along the line I-I′ of FIG. 5.

FIG. 7 is a sectional view of the display panel according to one or more embodiments of the present disclosure.

FIG. 8 is an enlarged plan view of a portion of a display area of a display panel according to one or more embodiments of the present disclosure.

FIG. 9 is a perspective view of a display device according to one or more embodiments of the present disclosure.

FIG. 10 is a sectional view taken along the line II-II′ of FIG. 9.

FIGS. 11A-11H are sectional views illustrating a manufacturing method of a display panel according to one or more embodiments of the present disclosure.

### DETAILED DESCRIPTION

In this specification, when a component (or, an area, a layer, a part, etc.) is referred to as being “on”, “connected to” or “coupled to” another component, this means that the component may be directly on, connected to, or coupled to the other component or a third component may be present therebetween.

In the detailed description and the drawings, identical reference numerals refer to identical components. Additionally, in the drawings, the thicknesses, proportions, and dimensions of components are exaggerated for effective description. As used herein, the term “and/or” includes all of one or more combinations defined by related components.

Terms such as first, second, and/or the like may be used to describe various components, but the components should not be limited by the terms. The terms may be used only for distinguishing one component from other components. For example, without departing the spirit and scope of the present disclosure, a first component may be referred to as a second component, and similarly, the second component may also be referred to as the first component. The terms of a singular form may include plural forms unless otherwise specified.

In addition, terms such as “below”, “under”, “above”, and “over” are used to describe a relationship between components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Throughout the present disclosure, the expression “at least one of a, b or c” indicates only a, only b, only c, both a and b, both a and c, both b and c, all of a, b, and c, or variations thereof.

Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments of the present disclosure will be described with reference to the accompanying drawings.

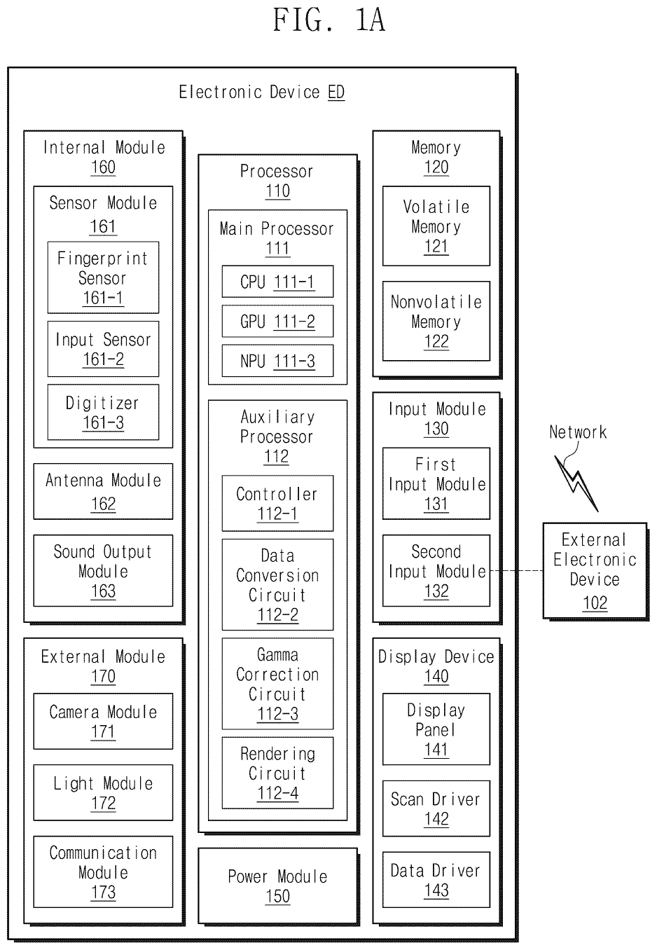

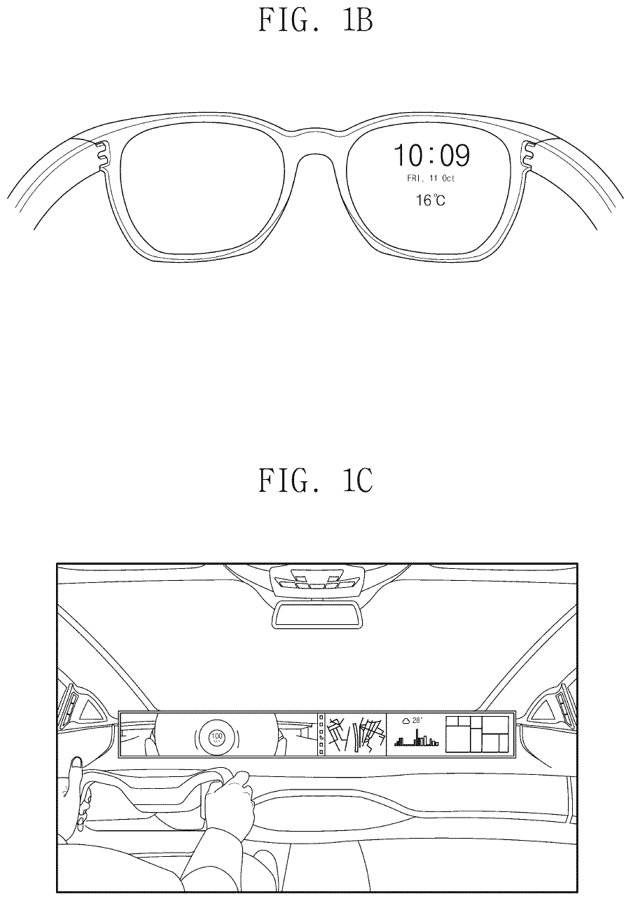

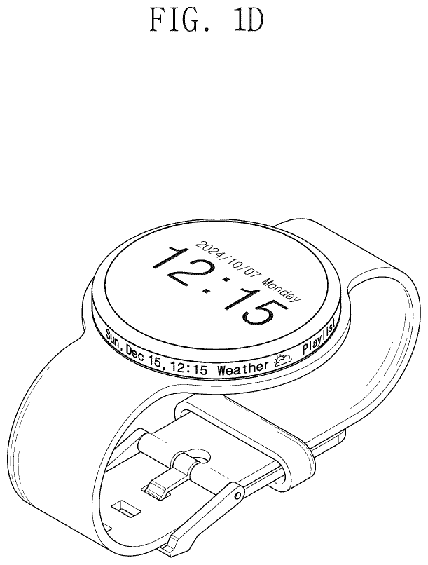

FIG. 1A is a block diagram of an electronic device ED according to one or more embodiments of the present disclosure. FIGS. 1B-1D are perspective views of the electronic device ED according to one or more embodiments of the present disclosure.

The electronic device ED according to one or more embodiments of the present disclosure includes a display device 140. As illustrated in FIGS. 1B-1D, the electronic device ED according to one or more embodiments of the present disclosure may be AR glasses, a vehicle display device, and/or a smart watch, but is not limited thereto.

As illustrated in FIG. 1A, the electronic device ED outputs a variety of information through the display device 140 in an operating system. When a processor 110 executes an application stored in a memory 120, the display device 140 provides a user with application information through a display panel 141.

The processor 110 obtains an external input through an input module 130 or a sensor module 161 and executes an application corresponding to the external input. For example, when the user selects a camera icon displayed on the display panel 141, the processor 110 obtains the user input through an input sensor 161-2 and activates a camera module 171. The processor 110 transfers image data corresponding to a photographed image obtained through the camera module 171 to the display device 140. The display device 140 may display an image corresponding to the photographed image through the display panel 141.

In another example, when authentication for personal information is performed in the display device 140, a fingerprint sensor 161-1 obtains the input fingerprint information as input data. The processor 110 compares the input data obtained through the fingerprint sensor 161-1 with authentication data stored in the memory 120 and executes an application depending on a comparison result. The display device 140 may display information executed depending on logic of the application, through the display panel 141.

In another example, when the user selects a music streaming icon displayed on the display device 140, the processor 110 obtains the user input through the input sensor 161-2 and activates a music streaming application stored in the memory 120. When a music play command is input to the music streaming application, the processor 110 activates a sound output module 163 and provides the user with sound information corresponding to the music play command.

The operation of the electronic device ED has been briefly described above. Hereinafter, a configuration of the electronic device ED will be described in detail. Some of the components of the electronic device ED to be described below may be integrally implemented with one component, and the one component may be divided into two or more components.

Referring to FIG. 1A, the electronic device ED may communicate with an external electronic device 102 over a network (e.g., a short-range wireless communication network or a long-range wireless communication network). According to one or more embodiments, the electronic device ED may include the processor 110, the memory 120, the input module 130, the display device 140, a power module 150, an internal module 160, and an external module 170. According to one or more embodiments, the electronic device ED may not include at least one of the above-described components or may further include one or more other components.

The processor 110 may execute software to control at least one component (e.g., a hardware or software component) of the electronic device ED connected with the processor 110 and may perform various data processing and/or operations.

The processor 110 may include a main processor 111 and an auxiliary processor 112. The main processor 111 may include at least one of a central processing unit (CPU) 111-1 or an application processor (AP). The main processor 111 may further include at least one of a graphic processing unit (GPU) 111-2, a neuron processing element (NPU) 111-3, a communication processor (CP), or an image signal processor (ISP).

The auxiliary processor 112 may include a controller 112-1. The controller 112-1 may include an interface conversion circuit and a timing control circuit. The controller 112-1 receives an image signal from the main processor 111 and outputs image data obtained by converting the data format of the image signal according to the specification of an interface with the display device 140. The controller 112-1 may output various types of control signals required to drive the display device 140.

The auxiliary processor 112 may further include a data conversion circuit 112-2, a gamma correction circuit 112-3, and a rendering circuit 112-4. The data conversion circuit 112-2 may receive image data from the controller 112-1; the data conversion circuit 112-2 may compensate for the image data such that an image is displayed with a desired luminance depending on a characteristic of the electronic device ED or user settings or may convert the image data to reduce power consumption or to compensate for afterimages. The gamma correction circuit 112-3 may convert the image data or the gamma reference voltage such that an image displayed on the electronic device ED has a desired gamma characteristic. The rendering circuit 112-4 may receive the image data from the controller 112-1 and may render the image data in consideration of a pixel arrangement of the display panel 141 applied to the electronic device ED. At least one of the data conversion circuit 112-2, the gamma correction circuit 112-3, or the rendering circuit 112-4 may be integrated into any other component (e.g., the main processor 111 or the controller 112-1). At least one of the data conversion circuit 112-2, the gamma correction circuit 112-3, or the rendering circuit 112-4 may be integrated into a data driver 143 to be described below.

The memory 120 may store various data used by at least one component (e.g., the processor 110 or the sensor module 161) of the electronic device ED and input data or output data for commands related thereto. The memory 120 may include at least one of a volatile memory 121 or a nonvolatile memory 122.

The input module 130 may receive a command or data to be used by a component (e.g., the processor 110, the sensor module 161, or the sound output module 163) of the electronic device ED from outside the electronic device ED (e.g., the user or the external electronic device 102).

The input module 130 may include a first input module 131 to which a command or data are input from the user and a second input module 132 to which a command or data are input from the external electronic device 102. The first input module 131 may include a microphone, a mouse, a keyboard, a key (e.g., a button), and/or a pen (e.g., a passive pen or an active pen). The second input module 132 may support a specified protocol capable of connecting to the external electronic device 102 by wire or wirelessly.

The display device 140 visually provides information to the user. The display device 140 may include the display panel 141, a scan driver 142, and the data driver 143. The display device 140 may further include a window, a chassis, and a bracket for protecting the display panel 141.

The display panel 141 may include a liquid crystal display panel, an organic light emitting display panel, or an inorganic light emitting display panel, and the type of the display panel 141 is not particularly limited. The display panel 141 may be of a rigid type or may be of a flexible type capable of being rolled and/or folded. The display device 140 may further include a supporter that supports the display panel 141, a bracket, and/or a heat radiating member.

The scan driver 142 may be mounted on the display panel 141 as a driver chip. In addition, the scan driver 142 may be integrated into the display panel 141. The scan driver 142 receives a control signal from the controller 112-1 and outputs scan signals to the display panel 141 in response to the control signal.

The display panel 141 may further include an emission driver. The emission driver outputs an emission control signal to the display panel 141 in response to a control signal received from the controller 112-1. The emission driver may be formed separately from the scan driver 142 or may be integrated into the scan driver 142.

The data driver 143 receives a control signal from the controller 112-1, converts image data into analog voltages (e.g., data voltages) in response to the control signal, and outputs the data voltages to the display panel 141.

The data driver 143 may be integrated into another component (e.g., the controller 112-1). The functions of the interface conversion circuit and the timing control circuit of the controller 112-1 described above may be integrated into the data driver 143.

The display device 140 may further include the emission driver and a voltage generation circuit. The voltage generation circuit may output various types of voltages required to drive the display panel 141.

The power module 150 supplies power to the components of the electronic device ED. The power module 150 may include a battery that charges a power supply voltage. The battery may include a primary cell that is not rechargeable, a secondary cell that is rechargeable, and/or a fuel cell. The power module 150 may include a power management integrated circuit (PMIC). The PMIC supplies power optimized for each of the modules described above and modules to be described below. The power module 150 may include a wireless power transmission/reception member electrically connected with the battery. The wireless power transmission/reception member may include a plurality of antenna radiators in the form of a coil.

The electronic device ED may further include the internal module 160 and the external module 170. The internal module 160 may include the sensor module 161, an antenna module 162, and the sound output module 163. The external module 170 may include the camera module 171, a light module 172, and a communication module 173.

The sensor module 161 may sense an input by the user's body or an input by a pen of the first input module 131 and may generate an electrical signal or a data value corresponding to the input. The sensor module 161 may include at least one of the fingerprint sensor 161-1, the input sensor 161-2, or a digitizer 161-3.

The fingerprint sensor 161-1 may generate a data value corresponding to the user's fingerprint. The fingerprint sensor 161-1 may include one of an optical fingerprint sensor or a capacitive fingerprint sensor.

The input sensor 161-2 may generate a data value corresponding to coordinate information of the input by the user's body or the input by the pen. The input sensor 161-2 generates a capacitance change due to the input as a data value. The input sensor 161-2 may sense the input by the passive pen or may exchange data with the active pen.

The input sensor 161-2 may measure a biometric signal such as blood pressure, moisture, and/or body fat.

The digitizer 161-3 may generate a data value corresponding to the coordinate information of the input by the pen. The digitizer 161-3 generates the amount of electromagnetic change by the input as a data value. The digitizer 161-3 may sense the input by the passive pen and/or may exchange data with the active pen.

At least one of the fingerprint sensor 161-1, the input sensor 161-2, or the digitizer 161-3 may be implemented with a sensor layer formed on the display panel 141 through a continuous process. The fingerprint sensor 161-1, the input sensor 161-2, and the digitizer 161-3 may be disposed above/on the display panel 141, and one of the fingerprint sensor 161-1, the input sensor 161-2, or the digitizer 161-3, for example, the digitizer 161-3 may be disposed below/under the display panel 141.

At least two of the fingerprint sensor 161-1, the input sensor 161-2, and the digitizer 161-3 may be integrated into one sensing panel through the same process. When they are integrated into one sensing panel, the sensing panel may be disposed between the display panel 141 and the window disposed above/on the display panel 141. According to one or more embodiments, the sensing panel may be disposed on the window, and the location of the sensing panel is not particularly limited.

At least one of the fingerprint sensor 161-1, the input sensor 161-2, or the digitizer 161-3 may be embedded in the display panel 141. That is, at least one of the fingerprint sensor 161-1, the input sensor 161-2, or the digitizer 161-3 may be concurrently (e.g., simultaneously) formed through a process of forming elements (e.g., a light emitting element and transistors) included in the display panel 141.

In addition, the sensor module 161 may generate an electrical signal or a data value corresponding to an internal state or an external state of the electronic device ED. The sensor module 161 may further include, for example, a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, and/or an illuminance sensor.

The antenna module 162 may include one or more antennas to transmit and/or receive a signal or power to or from an external source. According to one or more embodiments, through an antenna suitable for a communication scheme, the communication module 173 may transmit a signal to an external electronic device or may receive a signal from the external electronic device. An antenna pattern of the antenna module 162 may be integrated with one component (e.g., the display panel 141) of the display device 140 and/or the input sensor 161-2.

The sound output module 163 that is a device for outputting a sound signal to the outside of the electronic device ED may include, for example, a speaker used for general purposes such as multimedia playback and/or recording playback and a receiver used exclusively for receiving calls. According to one or more embodiments, the receiver and the speaker may be either integrally or separately implemented. A sound output pattern of the sound output module 163 may be integrated with the display device 140.

The camera module 171 may take a still image and/or a moving image. According to one or more embodiments, the camera module 171 may include one or more lenses, an image sensor, and/or an image signal processor. The camera module 171 may further include an infrared camera capable of measuring the presence or absence of the user, the location of the user, and/or the line of sight of the user.

The light module 172 may provide light. The light module 172 may include a light emitting diode or a xenon lamp. The light module 172 may operate in conjunction with the camera module 171 or may operate independently.

The communication module 173 may establish a wired or wireless communication channel between the electronic device ED and the external electronic device 102 and may support communication execution through the established communication channel. The communication module 173 may include either or both of a wireless communication module, such as a cellular communication module, a short-range wireless communication module, and/or a global navigation satellite system (GNSS) communication module, and a wired communication module, such as a local area network (LAN) communication module or a power line communication module. The communication module 173 may communicate with the external electronic device 102 over a short-range communication network such as Bluetooth, Wi-Fi direct, and/or infrared data association (IrDA) or a long-range communication network such as a cellular network, the Internet, and/or a computer network (e.g., a LAN or WAN). Various types of communication modules described above may be implemented with one chip or with separate chips, respectively.

The input module 130, the sensor module 161, and the camera module 171 may be used to control the operation of the display device 140 in conjunction with the processor 110.

The processor 110 outputs commands and/or data to the display device 140, the sound output module 163, the camera module 171, and/or the light module 172 based on the input data received from the input module 130.

The processor 110 outputs commands or data to the display device 140, the sound output module 163, the camera module 171, or the light module 172 based on the sensing data received from the sensor module 161. For example, the processor 110 may compare authentication data obtained through the fingerprint sensor 161-1 with authentication data stored in the memory 120 and may then execute an application depending on a comparison result. The processor 110 may execute a command based on the sensing data sensed by the input sensor 161-2 or the digitizer 161-3 or may output image data corresponding to the sensing data to the display device 140. When the sensor module 161 includes a temperature sensor, the processor 110 may receive temperature data associated with the measured temperature from the sensor module 161 and may further perform luminance correction on the image data based on the temperature data.

The processor 110 may receive measurement data about the presence or absence of the user, the location of the user, and the line of sight of the user from the camera module 171. The processor 110 may further perform the luminance correction on the image data based on the measurement data. For example, the processor 110 that determines the presence or absence of the user through the input from the camera module 171 may output, to the display device 140, image data whose luminance is corrected through the data conversion circuit 112-2 or the gamma correction circuit 112-3.

Some of the components described above may be connected with each other through a communication scheme between peripheral devices, for example, a bus, a general purpose input/output (GPIO), a serial peripheral interface (SPI), a mobile industry processor interface (MIPI), or a ultra path interconnect (UPI) link and may exchange signals (e.g., commands or data). The processor 110 may communicate with the display device 140 through a given interface. For example, one of the communication methods described above may be used, and the present disclosure is not limited thereto.

The electronic device ED according to various embodiments of the present disclosure may be implemented as various types of devices. The electronic device ED may include, for example, at least one of a portable communication device (e.g., a smart phone), a tablet device, a portable multimedia device, a wearable device, or home appliances. The electronic device ED according to one or more embodiments of the present disclosure is not limited to the above-described devices. The augmented reality (AR) glasses illustrated in FIG. 1B, the vehicle display device illustrated in FIG. 1C, and the smart watch illustrated in FIG. 1D may be implemented with the electronic device of the present disclosure.

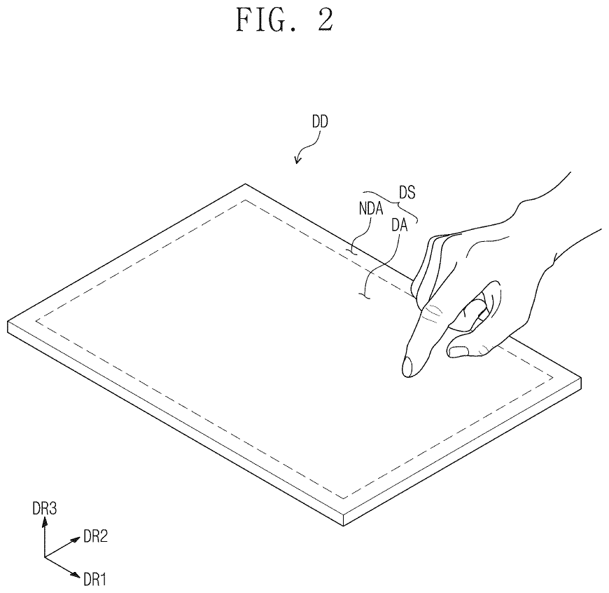

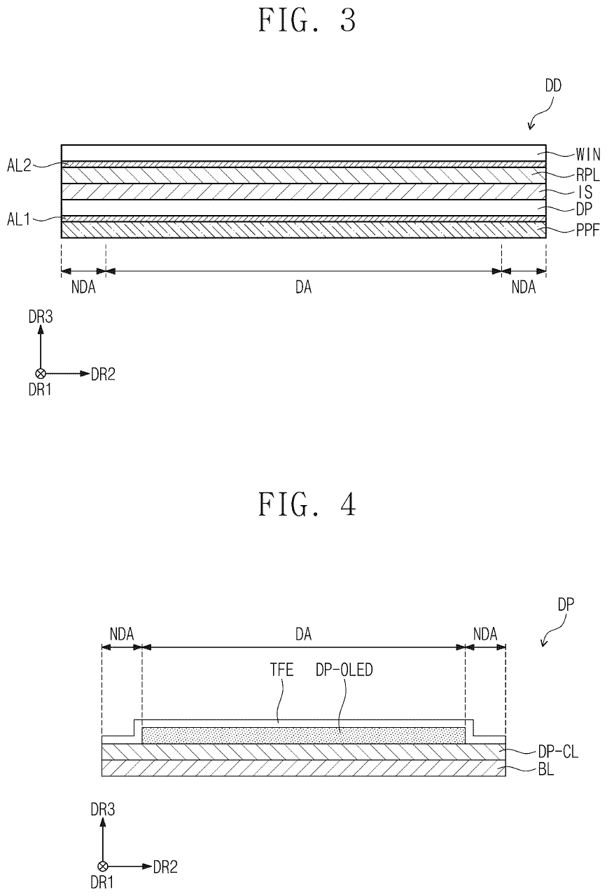

FIG. 2 is a perspective view of a display device DD according to one or more embodiments of the present disclosure.

Referring to FIG. 2, the display device DD according to one or more embodiments of the present disclosure may have a rectangular shape with long sides extending in a first direction DR1 and short sides extending in a second direction DR2 crossing the first direction DR1. However, without being limited thereto, the display device DD may have various shapes such as a circular shape, a polygonal shape, and/or the like. Hereinafter, a direction substantially perpendicular to a plane defined by the first direction DR1 and the second direction DR2 is defined as a third direction DR3. The expression “when viewed from above the plane” (e.g., in a plan view) used herein may mean that it is viewed in the third direction DR3.

The upper surface of the display device DD may be defined as a display surface DS and may have a plane defined by the first direction DR1 and the second direction DR2. Images generated by the display device DD may be provided to a user through the display surface DS.

The display surface DS may include a display area DA and a non-display area NDA around the display area DA along an edge or a periphery of the display area DA. The display area DA displays an image, and the non-display area NDA does not display an image. The non-display area NDA may be around (e.g., may surround) the display area DA. However, without being limited thereto, the non-display area NDA may not be disposed on one side of the display area DA.

FIG. 3 is a sectional view of the display device DD illustrated in FIG. 2.

Referring to FIG. 3, the display device DD may include a display panel DP, an input sensor IS, an anti-reflective layer RPL, a window WIN, a panel protection film PPF, a first adhesive layer AL1, and a second adhesive layer AL2. In one or more embodiments of the present disclosure, the input sensor IS may be omitted.

The display panel DP according to one or more embodiments of the present disclosure may be an emissive display panel, but is not particularly limited. For example, the display panel DP may be an organic light emitting display panel or an inorganic light emitting display panel. An emissive layer of the organic light emitting display panel may include an organic luminescent material. An emissive layer of the inorganic light emitting display panel may include quantum dots and quantum rods. Hereinafter, it will be exemplified that the display panel DP is an organic light emitting display panel.

The input sensor IS may be disposed on the display panel DP. The input sensor IS may include a plurality of sensors for sensing an external input in a capacitance type. The input sensor IS may be directly formed on the display panel DP when the display device DD is manufactured. However, without being limited thereto, the input sensor IS may be manufactured as a panel separate from the display panel DP and may be attached to the display panel DP by an adhesive layer.

The anti-reflective layer RPL may be disposed on the input sensor IS. The anti-reflective layer RPL may be directly formed on the input sensor IS when the display device DD is manufactured. The anti-reflective layer RPL may include color filters and may further include a black matrix.

However, without being limited thereto, the anti-reflective layer RPL may be manufactured as a separate panel and may be attached to the input sensor IS through an adhesive layer. The anti-reflective layer RPL may include an optical film such as a polarizer film. The anti-reflective layer RPL may decrease the reflectance of external light incident toward the display panel DP from above the display device DD. The external light may not be visible to the user due to the anti-reflective layer RPL.

The window WIN may be disposed on the anti-reflective layer RPL. The window WIN may protect the display panel DP, the input sensor IS, and the anti-reflective layer RPL from external scratches and/or impacts.

The panel protection film PPF may be disposed under the display panel DP. The panel protection film PPF may protect the bottom of the display panel DP. The panel protection film PPF may include a flexible plastic material such as polyethylene terephthalate (PET).

FIG. 4 is a sectional view of the display panel DP illustrated in FIG. 3.

Referring to FIG. 4, the display panel DP may include a base layer BL, a circuit element layer DP-CL disposed on the base layer BL, a display element layer DP-OLED disposed on the circuit element layer DP-CL, and a thin film encapsulation layer TFE disposed on the display element layer DP-OLED.

The base layer BL may include a display area DA and a non-display area NDA around the display area DA, like the display device DD of FIG. 2. The base layer BL may include a flexible plastic material such as polyimide (PI) or glass.

The circuit element layer DP-CL may include a driving circuit of a light emitting element and a driving circuit of a light sensing element. The display element layer DP-OLED may include the light emitting element and the light sensing element. The thin film encapsulation layer TFE may be disposed on the circuit element layer DP-CL to cover the display element layer DP-OLED. The thin film encapsulation layer TFE may protect pixels from moisture, oxygen, and/or external foreign matter.

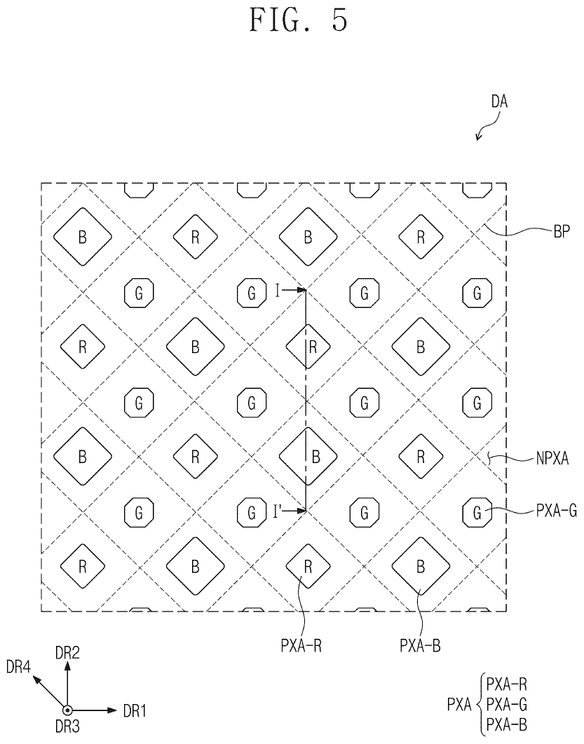

FIG. 5 is an enlarged plan view of a portion of the display area DA of the display panel DP according to one or more embodiments of the present disclosure.

Referring to FIG. 5, the display area DA may include first to third emissive areas PXA-R, PXA-G, and PXA-B and a non-emissive area NPXA surrounding the first to third emissive areas PXA-R, PXA-G, and PXA-B. The emissive areas PXA may correspond to areas where light provided from light emitting elements is emitted. The emissive areas PXA may be distinguished from one another depending on the colors of light emitted toward the outside of the display panel DP (refer to FIG. 4).

The first to third emissive areas PXA-R, PXA-G, and PXA-B may provide light of a first color, light of a second color, and light of a third color that have different colors, respectively. For example, the light of the first color may be red light, the light of the second color may be green light, and the light of the third color may be blue light. However, examples of the light of the first color, the light of the second color, and the light of the third color are not necessarily limited thereto.

Each of the emissive areas PXA may be defined as an area where the upper surface of a first electrode is exposed by a light emitting opening EOP to be described below. The non-emissive area NPXA may set the boundaries between the emissive areas PXA and may prevent color mixing between the emissive areas PXA.

One second emissive area PXA-G may be spaced (e.g., spaced apart) from one first emissive area PXA-R or one third emissive area PXA-B in a fourth direction DR4. The fourth direction DR4 may be defined as a direction between the first direction DR1 and the second direction DR2.

In FIG. 5, the arrangement of the first to third emissive areas PXA-R, PXA-G, and PXA-B is illustrated as an example, and without being limited thereto, the first to third emissive areas PXA-R, PXA-G, and PXA-B may be arranged in various forms. In one or more embodiments, the first to third emissive areas PXA-R, PXA-G, and PXA-B may have a PENTILE® arrangement as illustrated in FIG. 5. This PENTILE® arrangement structure may be referred to as an RGBG matrix structure (e.g., a PENTILE® matrix structure or an RGBG structure (e.g., a PENTILE® structure)). PENTILE® is a registered trademark of Samsung Display Co., Ltd., Republic of Korea. Alternatively, the first to third emissive areas PXA-R, PXA-G, and PXA-B may have a stripe arrangement or a Diamond Pixel® arrangement.

The first to third emissive areas PXA-R, PXA-G, and PXA-B may have various shapes when viewed from above the plane (e.g., in a plan view). For example, the first to third emissive areas PXA-R, PXA-G, and PXA-B may have a polygonal shape, a circular shape, or an oval shape. FIG. 5 illustrates the first emissive area PXA-R and the third emissive area PXA-B that have a quadrangular shape (or, a rhombus shape) when viewed from above the plane (e.g., in a plan view) and the second emissive area PXA-G that has an octagonal shape when viewed from above the plane (e.g., in a plan view).

When viewed from above the plane (e.g., in a plan view), the first to third emissive areas PXA-R, PXA-G, and PXA-B may have the same shape, or at least some of the first to third emissive areas PXA-R, PXA-G, and PXA-B may have different shapes. FIG. 5 illustrates the first emissive area PXA-R and the third emissive area PXA-B that have the same shape when viewed from above the plane (e.g., in a plan view) and the second emissive area PXA-G that has a shape different from those of the first emissive area PXA-R and the third emissive area PXA-B when viewed from above the plane (e.g., in a plan view).

At least some of the emissive areas PXA may have different areas when viewed from above the plane. In one or more embodiments, the area of the first emissive area PXA-R emitting red light may be greater than the area of the second emissive area PXA-G emitting green light and may be smaller than the area of the third emissive area PXA-B emitting blue light. However, the relationship between the areas of the first emissive area PXA-R, the second emissive area PXA-G, and the third emissive area PXA-B depending on the colors of emitted light is not limited thereto and may vary depending on the design of the display panel DP. Furthermore, without being limited thereto, the first to third emissive areas PXA-R, PXA-G, and PXA-B may have the same area when viewed from above the plane (e.g., in a plan view).

In one or more embodiments, the shapes, areas, and arrangement of the emissive areas PXA of the display area DA of the present disclosure may be designed in various ways depending on the colors of emitted light and the size and configuration of the display panel DP and are not limited to the embodiment illustrated in FIG. 5.

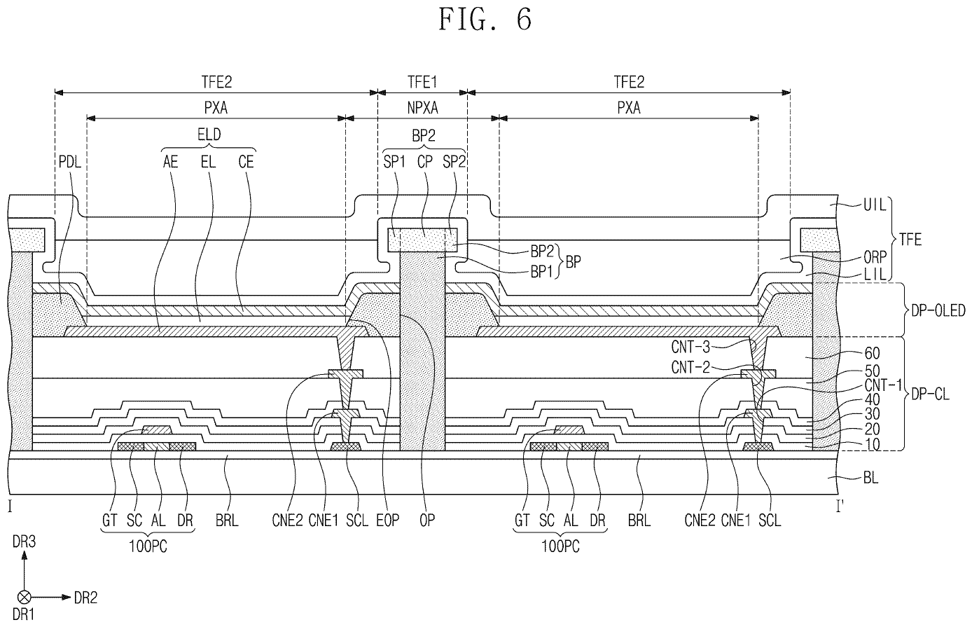

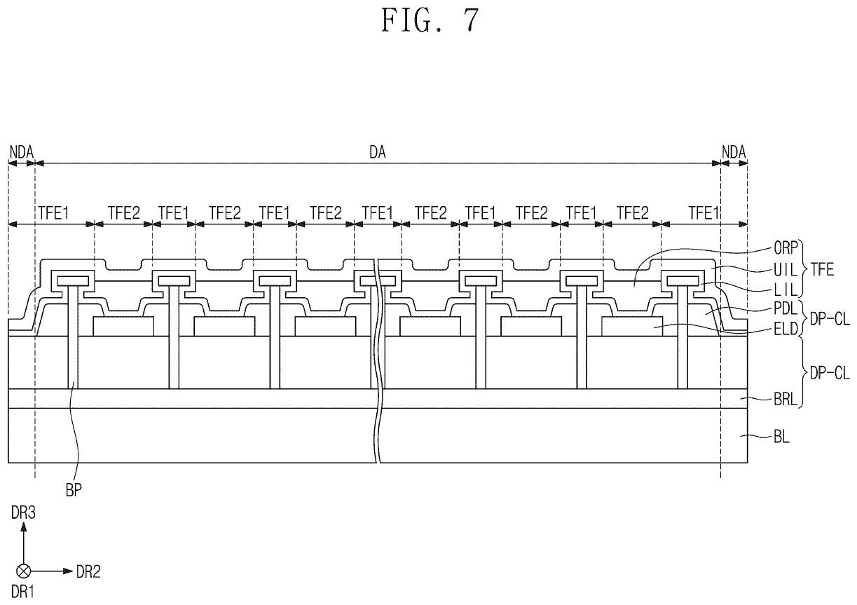

FIG. 6 is a sectional view taken along the line I-I′ of FIG. 5. FIG. 7 is a sectional view of the display panel DP according to one or more embodiments of the present disclosure. FIG. 6 is a more enlarged view of a portion when compared to FIG. 7.

Referring to FIG. 6, at least one inorganic layer may be disposed on the upper surface of the base layer BL. The at least one inorganic layer may prevent infiltration of moisture from below the base layer BL or may increase the coupling force of a semiconductor pattern SC, AL, DR, and SCL to be described below.

The at least one inorganic layer may include a barrier layer BRL. The barrier layer BRL may be in contact with the base layer BL. The barrier layer BRL may include silicon nitride having a high moisture blocking effect. The barrier layer BRL may include a plurality of silicon nitride layers.

The at least one inorganic layer may further include a non-illustrated buffer layer. The buffer layer may be disposed between the base layer BL and the semiconductor pattern SC, AL, DR, and SCL and may improve the coupling force between the base layer BL and the semiconductor pattern SC, AL, DR, and SCL. In addition, the buffer layer may block impurities from moving to the semiconductor pattern SC, AL, DR, and SCL from below. The buffer layer may include at least one of a silicon oxide layer or a silicon nitride layer. The buffer layer may be omitted.

The semiconductor pattern SC, AL, DR, and SCL may be disposed on the barrier layer BRL. The semiconductor pattern SC, AL, DR, and SCL may include poly silicon. However, without being limited thereto, the semiconductor pattern SC, AL, DR, and SCL may include amorphous silicon, low-temperature polycrystalline silicon, and/or an oxide semiconductor.

FIG. 6 illustrates only a portion of the semiconductor pattern SC, AL, DR, and SCL, and semiconductor patterns may be additionally disposed in other areas. The semiconductor pattern SC, AL, DR, and SCL may be arranged according to a specific rule across pixels. The semiconductor pattern SC, AL, DR, and SCL may have different electrical properties depending on whether doping is performed or not. The semiconductor pattern SC, AL, DR, and SCL may include first areas SC, DR, and SCL having a high conductivity and a second area AL having a low conductivity. The first areas SC, DR, and SCL may be doped with an N-type dopant or a P-type dopant. A P-type transistor may include a doped area doped with a P-type dopant, and an N-type transistor may include a doped area doped with an N-type dopant. The second area AL may be a non-doped area or may be an area more lightly doped than the first areas SC, DR, and SCL.

The first areas SC, DR, and SCL may have a higher conductivity than the second area AL and may substantially serve as electrodes or signal lines. The second area AL may substantially correspond to an active area AL (or, a channel) of a transistor 100PC. In other words, the second area AL of the semiconductor pattern SC, AL, DR, and SCL may be the active area AL of the transistor 100PC, another portion SC or DR may be a source area SC or a drain area DR of the transistor 100PC, and the other portion SCL may be a connecting electrode or a connecting signal line SCL.

Each of the pixels may have an equivalent circuit including a plurality of transistors, at least one capacitor, and at least one light emitting element, and the equivalent circuit of the pixel may be modified in various forms. FIG. 6 illustrates the transistor 100PC and a light emitting element ELD included in the pixel.

The source area SC, the active area AL, and the drain area DR of the transistor 100PC may be formed from the semiconductor pattern SC, AL, DR, and SCL. The source area SC and the drain area DR may extend from the active area AL in opposite directions on the cross-section. In one or more embodiments, the connecting signal line SCL may be connected to the drain area DR of the transistor 100PC when viewed from above the plane (e.g., in a plan view).

At least one intermediate insulating layer 10 to 60 is disposed on the barrier layer BRL. In this embodiment, the at least one intermediate insulating layer 10 to 60 may include the first to sixth insulating layers 10 to 60.

The first insulating layer 10 may be disposed on the barrier layer BRL. The first insulating layer 10 may commonly overlap the plurality of pixels and may cover the semiconductor pattern SC, AL, DR, and SCL. The first insulating layer 10 may be an inorganic layer and/or an organic layer and may have a single-layer structure or a multi-layer structure. The first insulating layer 10 may include aluminum oxide, titanium oxide, silicon oxide, silicon nitride, silicon oxynitride, zirconium oxide, and/or hafnium oxide. In this embodiment, the first insulating layer 10 may be a single silicon oxide layer. Not only the first insulating layer 10 but also the insulating layers of the circuit layer DP-CL to be described below may be inorganic layers and/or organic layers and may have a single-layer structure or a multi-layer structure. The inorganic layers may include at least one of the aforementioned materials, but are not limited thereto.

A gate GT of the transistor 100PC is disposed on the first insulating layer 10. The gate GT may be a portion of a metal pattern. The gate GT overlaps the active area AL in the third direction DR3. The gate GT may function as a mask in a process of doping or reducing the semiconductor pattern SC, AL, DR, and SCL.

The second insulating layer 20 may be disposed on the first insulating layer 10 and may cover the gate GT. The second insulating layer 20 may commonly overlap the pixels. The third insulating layer 30 may be disposed on the second insulating layer 20. A first connecting electrode CNE1 may be disposed on the third insulating layer 30. The first connecting electrode CNE1 may be connected to the connecting signal line SCL through a contact hole CNT-1 that passes through the first insulating layer 10, the second insulating layer 20, and the third insulating layer 30.

The fourth insulating layer 40 may be disposed on the third insulating layer 30. The fourth insulating layer 40 may cover the first connecting electrode CNE1. The fifth insulating layer 50 may be disposed on the fourth insulating layer 40. The fifth insulating layer 50 may be an organic layer. A second connecting electrode CNE2 may be disposed on the fifth insulating layer 50. The second connecting electrode CNE2 may be connected to the first connecting electrode CNE1 through a contact hole CNT-2 that passes through the fourth insulating layer 40 and the fifth insulating layer 50. The sixth insulating layer 60 may be disposed on the fifth insulating layer 50 and may cover the second connecting electrode CNE2. The sixth insulating layer 60 may be an organic layer.

The display element layer DP-OLED may be disposed on the circuit element layer DP-CL. The display element layer DP-OLED may include the light emitting element ELD. For example, an emissive layer EL of the light emitting element ELD that will be described below may include an organic luminescent material, an inorganic luminescent material, an organic-inorganic luminescent material, a quantum dot, a quantum rod, a micro LED, or a nano LED. Hereinafter, it will be discussed as an example that the light emitting element ELD is an organic light emitting element. However, the present disclosure is not particularly limited thereto.

The light emitting element ELD may include a first electrode AE, the emissive layer EL, and a second electrode CE. The first electrode AE may be electrically connected to the transistor 100PC. The first electrode AE may be connected to the second connecting electrode CNE2 through a contact hole CNT-3 that passes through the sixth insulating layer 60. The first electrode AE may be a transmissive electrode, a transflective electrode, or a reflective electrode. Accordingly, the electrode AE may be electrically connected to the connecting signal line SCL through the first connecting electrode CNE1 and the second connecting electrode CNE2 and may be electrically connected to a corresponding circuit element. The first electrode AE may have a single-layer structure or a multi-layer structure. The first electrode AE may include a plurality of layers including indium tin oxide (ITO) and/or silver (Ag).

In one or more embodiments of the present disclosure, the emissive layer EL may be separately formed in each of the light emitting elements. When the emissive layer EL is separately formed in each of the light emitting elements, each of the emissive layers EL may emit at least one of blue light, red light, or green light. However, without being limited thereto, the emissive layer EL may have a one-body shape and may be commonly included in the plurality of pixels. In this case, the emissive layer EL may provide blue light or white light.

The second electrode CE may be disposed on the emissive layer EL. The second electrode CE may be separately formed in each of the pixels by a barrier pattern BP to be described below. However, without being limited thereto, the second electrode CE may have a one-body shape and may be commonly included in the plurality of light emitting elements and the barrier pattern BP.

In one or more embodiments of the present disclosure, a hole control layer may be disposed between the first electrode AE and the emissive layer EL. The hole control layer may be commonly disposed in the emissive area PXA and the non-emissive area NPXA. The hole control layer may include a hole transport layer and may further include a hole injection layer. An electron control layer may be disposed between the emissive layer EL and the second electrode CE. The electron control layer may include an electron transport layer and may further include an electron injection layer. The hole control layer and the electron control layer may be commonly formed in the plurality of pixels using an open mask or an ink-jet process.

A pixel defining layer PDL may be disposed on the sixth insulating layer 60 and may cover a portion of the first electrode AE. The pixel defining layer PDL may have the light emitting opening EOP defined therein. The light emitting opening EOP of the pixel defining layer PDL may correspond to the first electrode AE and may expose at least a portion of the first electrode AE.

In this embodiment, the emissive area PXA is defined to correspond to a partial area of the first electrode AE exposed by the light emitting opening EOP. The non-emissive area NPXA is defined to correspond to the pixel defining layer PDL.

The barrier pattern BP connects the barrier layer BRL and a first inorganic encapsulation layer LIL in the third direction DR3 and stably protects internal structures of the display panel DP from external impact, oxygen, and/or moisture.

The barrier pattern BP may be in contact with the at least one inorganic layer through an opening OP that passes through the intermediate insulating layers 10 to 60 and the pixel defining layer PDL. The at least one inorganic layer may include the barrier layer BRL disposed between the semiconductor pattern SC, AL, DR, and SCL and the base layer BL.

One portion of the barrier pattern BP may protrude above the pixel defining layer PDL. As the one portion of the barrier pattern BP protrudes above the pixel defining layer PDL, the second electrode CE may be physically separated by the barrier pattern BP.

The barrier pattern BP may include two or more portions having different etch rates. The barrier pattern BP may include a first metal portion BP1 inserted into the opening OP that passes through the at least one intermediate insulating layer 10 to 60 and the pixel defining layer PDL and a second metal portion BP2 protruding above the pixel defining layer PDL. The second metal portion BP2 may be disposed on the first metal portion BP1. The second metal portion BP2 may be spaced (e.g., spaced apart) from the pixel defining layer PDL in the third direction DR3.

The second metal portion BP2 may include a central portion CP that overlaps the first metal portion BP1 in the third direction DR3 and a first side portion SP1 and a second side portion SP2 that do not overlap the first metal portion BP1 in the third direction DR3. The central portion CP may be disposed between the first side portion SP1 and the second side portion SP2. The second metal portion BP2 may have a greater width (e.g., in the first direction DR1 or the second direction DR2) than the first metal portion BP1. The second metal portion BP2 may be a tip structure protruding from the first metal portion BP1 on the plane (e.g., in a plan view). The barrier pattern BP may have a T-shape on the cross-section.

In one or more embodiments, the barrier pattern BP may include one metal or two or more metals and may be a straight structure or a stepped structure further including a step depending on the type of metal, the etch rate, and the width of the opening OP.

In this embodiment, a plurality of barrier patterns BP may be spaced (e.g., spaced apart) from one another, and the light emitting element ELD may be located between adjacent barrier patterns BP. As illustrated in FIG. 5, when viewed from above the plane (e.g., in a plan view), the barrier pattern BP may be around (e.g., may surround) each of the emissive areas PXA on the plane defined by the first direction DR1 and the second direction DR2. The barrier pattern BP may be formed to be around (e.g., to surround) one or more light emitting elements ELD in a closed-loop shape and may more effectively protect the light emitting elements ELD from external contamination.

In one or more embodiments of the present disclosure, the thin film encapsulation layer TFE may be disposed on the display element layer DP-OLED and the barrier pattern BP. The thin film encapsulation layer TFE may include the first inorganic encapsulation layer LIL, an organic pattern ORP, and a second inorganic encapsulation layer UIL. The first inorganic encapsulation layer LIL and the second inorganic encapsulation layer UIL may protect the display element layer DP-OLED from moisture and/or oxygen, and the organic pattern ORP may separate pin holes that surround foreign material such as dust particles and that are generated in the first inorganic encapsulation layer LIL and the second inorganic encapsulation layer UIL by the foreign material.

The first inorganic encapsulation layer LIL may cover the second electrode CE, the pixel defining layer PDL, and the protruding portion of the barrier pattern BP. The first inorganic encapsulation layer LIL may be deposited so as to be wider than the light emitting element ELD and may cover the second electrode CE. The first inorganic encapsulation layer LIL may cover the upper portion of the pixel defining layer PDL and may make contact with the barrier pattern BP. In addition, the first inorganic encapsulation layer LIL may be formed by a deposition process to be in contact with the side surface of the one portion protruding above the pixel defining layer PDL and surround the one portion protruding above the pixel defining layer PDL. The first inorganic encapsulation layer LIL may include silicon nitride SiNₓ, silicon oxide SiOₓ, and/or silicon oxynitride SiON.

The organic pattern ORP may overlap (or correspond to) the light emitting element ELD. When the organic pattern ORP overlaps the light emitting element ELD, this may mean that the organic pattern ORP is disposed to overlap the light emitting opening EOP. A plurality of organic patterns ORP may be provided to overlap the light emitting elements ELD, respectively.

The portions of the organic patterns ORP that correspond to the upper portion of the barrier pattern BP may all be etched and removed by an etching process during a manufacturing process. The organic patterns ORP may be formed to be spaced (e.g., spaced apart) from each other by a distance corresponding to the barrier pattern BP and the first inorganic encapsulation layer LIL therebetween.

The second inorganic encapsulation layer UIL may overlap the first inorganic encapsulation layer LIL and the organic pattern ORP. The thin film encapsulation layer TFE of the present disclosure may include a first thin film encapsulation area TFE1 (or, a first area) where the first inorganic encapsulation layer LIL and the second inorganic encapsulation layer UIL are in contact with each other and a second thin film encapsulation area TFE2 (or, a second area) where the organic pattern ORP is disposed between the first inorganic encapsulation layer LIL and the second inorganic encapsulation layer UIL.

The first thin film encapsulation area TFE1 of the present disclosure may correspond to a portion of the pixel defining layer PDL or the barrier pattern BP, and the second thin film encapsulation area TFE2 may correspond to the light emitting element ELD. The first inorganic encapsulation layer LIL and the second inorganic encapsulation layer UIL may be in direct contact with each other in the first thin film encapsulation area TFE1. Accordingly, the overall thickness of the thin film encapsulation layer TFE may be decreased. The second thin film encapsulation area TFE2 may include the organic pattern ORP between the first inorganic encapsulation layer LIL and the second inorganic encapsulation layer UIL and may separate pin holes generated in the first inorganic encapsulation layer LIL and the second inorganic encapsulation layer UIL by foreign matter over the light emitting element ELD.

FIG. 7 illustrates a form in which the barrier pattern BP described with reference to FIG. 6 is disposed in the entire display panel.

The display panel DP of FIG. 7 may be an internal structure of the display panel DP of FIG. 2.

Referring to FIG. 7, the non-display area NDA located outside the display area DA may be the first thin film encapsulation area TFE1. The thin film encapsulation layer TFE in the display area DA may include the first thin film encapsulation area TFE1 and the second thin film encapsulation area TFE2. In the display area DA, the first thin film encapsulation area TFE1 and the second thin film encapsulation area TFE2 may be alternately disposed along the second direction DR2.

The plurality of organic patterns ORP may overlap the light emitting elements ELD, respectively. The organic patterns ORP may be spaced (e.g., spaced apart) from one another. The barrier pattern BP may be located between the organic patterns ORP, and the first inorganic encapsulation layer LIL and the second inorganic encapsulation layer UIL may be in contact with each other on the barrier pattern BP.

Referring to FIG. 5, the area corresponding to the emissive area PXA when viewed from above the plane (e.g., in a plan view) may correspond to the second thin film encapsulation area TFE2 and may be surrounded by the barrier pattern BP. The first thin film encapsulation area TFE1 may correspond to the area where the barrier pattern BP is located. The first thin film encapsulation area TFE1 may be formed in a shape surrounding the second thin film encapsulation area TFE2.

Although FIGS. 5-7 illustrate the embodiment in which the barrier pattern BP surrounds each of the light emitting elements ELD, the barrier pattern BP is not limited thereto and may be implemented in various ways.

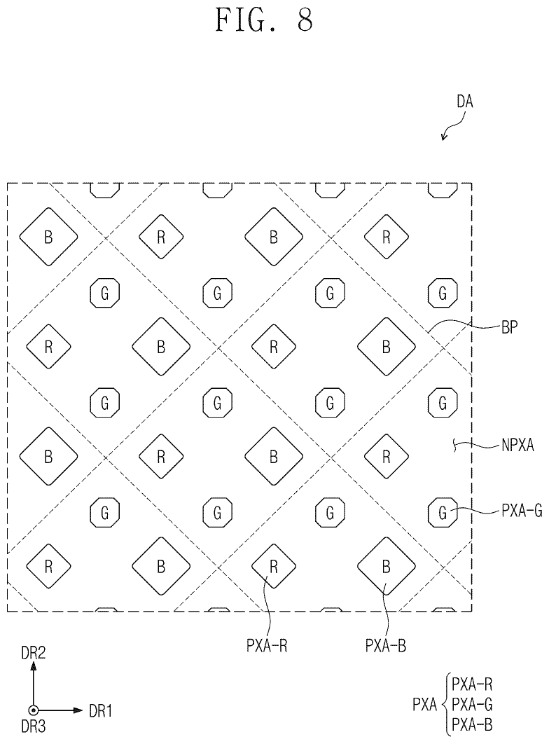

FIG. 8 is an enlarged plan view of a portion of a display area DA of a display panel DP according to one or more embodiments of the present disclosure.

Referring to FIG. 8, each of barrier patterns BP may be around (e.g., may surround) a plurality of emissive areas PXA in a closed-loop shape when viewed from above a plane (e.g., in a plan view). Each of the emissive areas PXA may include the light emitting element ELD (refer to FIG. 6), and the barrier pattern BP may be around (e.g., may surround) the plurality of light emitting elements ELD (refer to FIG. 6) in a closed-loop shape. The spacing between the barrier patterns BP and the number of light emitting elements ELD surrounded by each of the barrier patterns BP may be variably determined depending on selection by a designer or manufacturer.

In FIG. 8, the barrier patterns BP may be arranged at a constant interval, and thus the areas formed by the barrier patterns BP may have a constant area. However, without being limited thereto, on one display area DA, the barrier patterns BP may be arranged at different intervals or may be arranged to be around (e.g., to surround) emissive areas PXA having different areas.

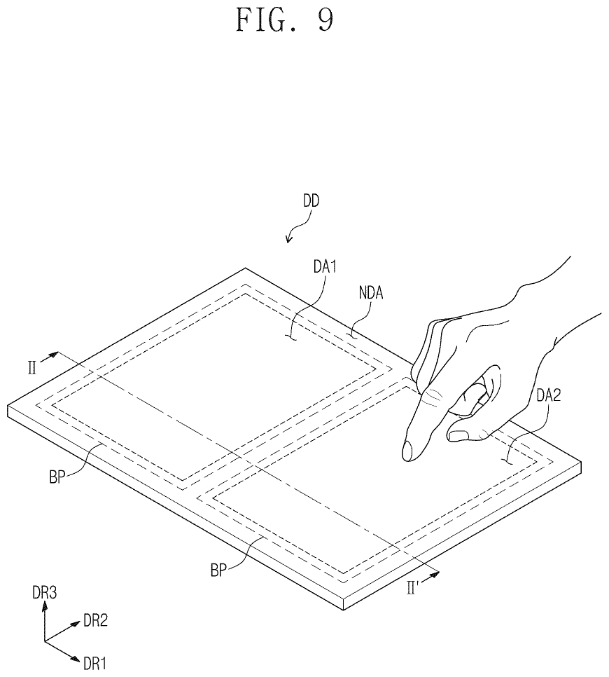

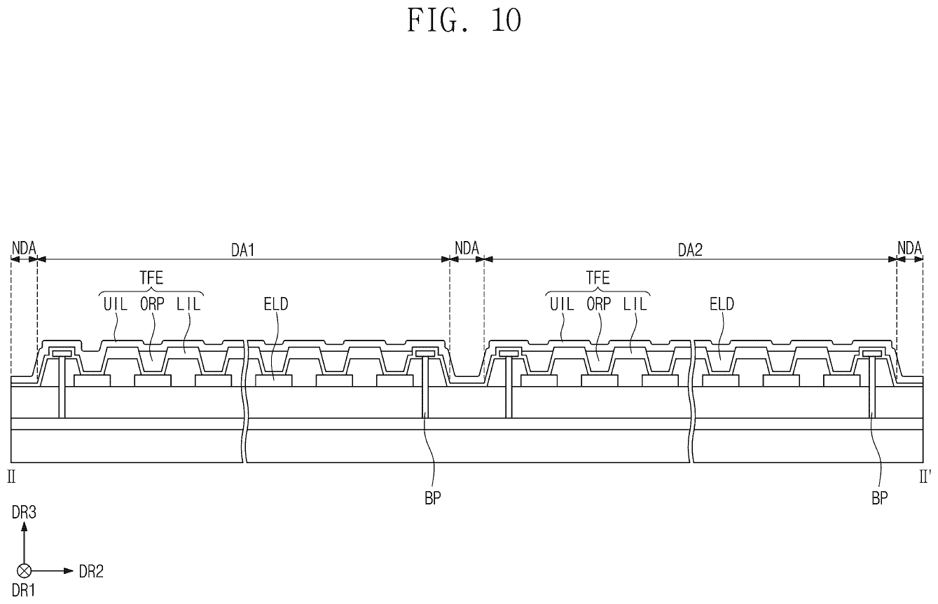

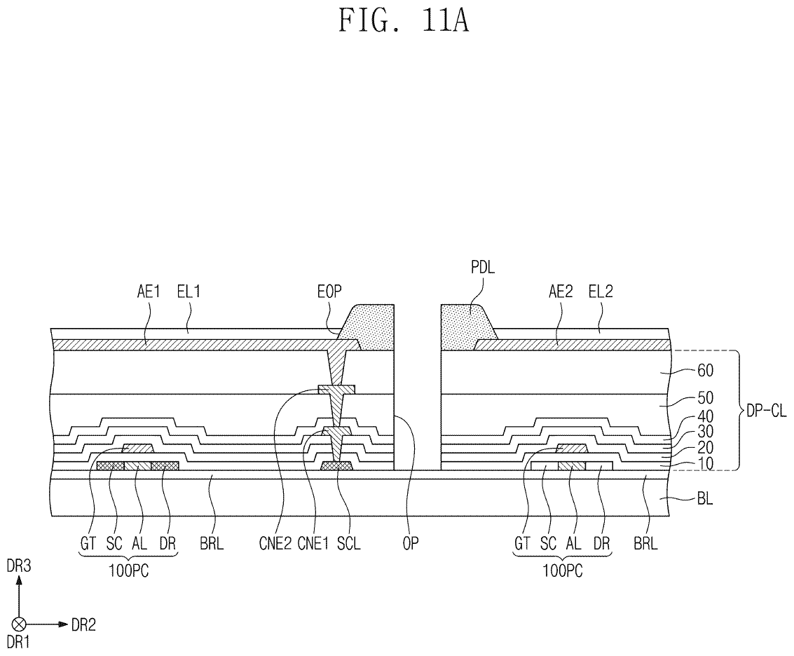

FIG. 9 is a perspective view of a display device DD according to one or more embodiments of the present disclosure. FIG. 10 is a sectional view taken along the line II-II′ of FIG. 9.

In one or more embodiments of the present disclosure, a display area of the display device DD may include two or more display areas DA1 and DA2. The display device DD of FIGS. 9 and 10 may be a stretchable display device in which a non-display area NDA between the first display area DA1 and the second display area DA2 has flexibility.

Barrier patterns BP may be formed to be around (e.g., to surround) the first display area DA1 and the second display area DA2, respectively. When the barrier patterns BP surround the display areas, this may mean that the barrier patterns BP surround light emitting elements ELD in the display areas. That is, the barrier patterns BP may be around (e.g., may surround) the plurality of light emitting elements ELD in a closed-loop shape.

Each of the first display area DA1 and the second display area DA2 includes the plurality of light emitting elements ELD. The barrier patterns BP may be located at the outermost sides of pixel defining layers PDL of the first display area DA1 and the second display area DA2. A thin film encapsulation layer TFE existing in the non-display area NDA disposed between the first display area DA1 and the second display area DA2 may be formed to be relatively thin because a first inorganic encapsulation layer LIL and a second inorganic encapsulation layer UIL make direct contact with each other. Accordingly, the flexibility of an area where mechanical deformation such as stretching occurs may be improved.

When the first display area DA1 and the second display area DA2 are disposed to be surrounded by the barrier patterns BP, respectively, a probability of damage to the light emitting elements ELD in the second display area DA2 may be lowered even though the light emitting elements ELD in the first display area DA1 are damaged.

Although FIG. 10 illustrates the case in which the barrier patterns BP are disposed at the peripheries of the first display area DA1 and the second display area DA2, the barrier patterns BP may be additionally disposed within the display areas DA1 and DA2.

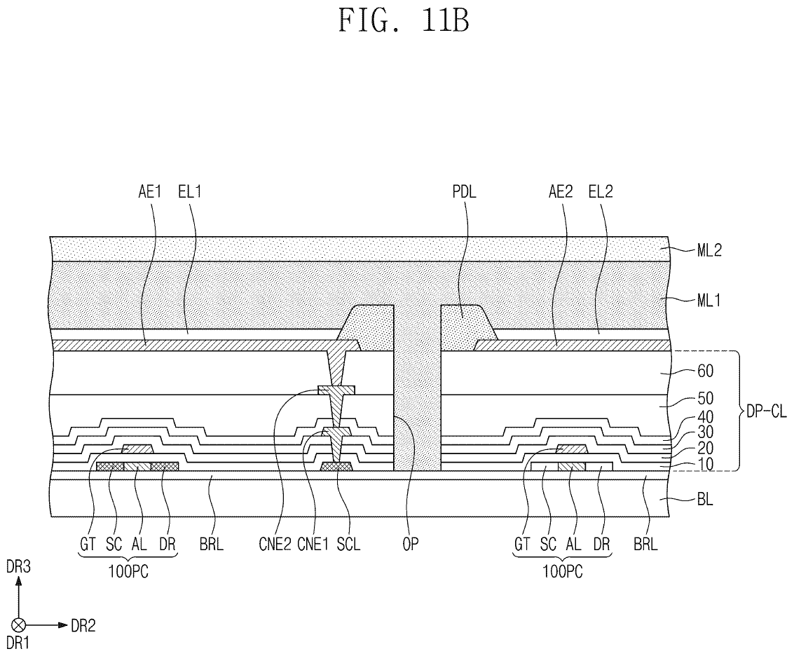

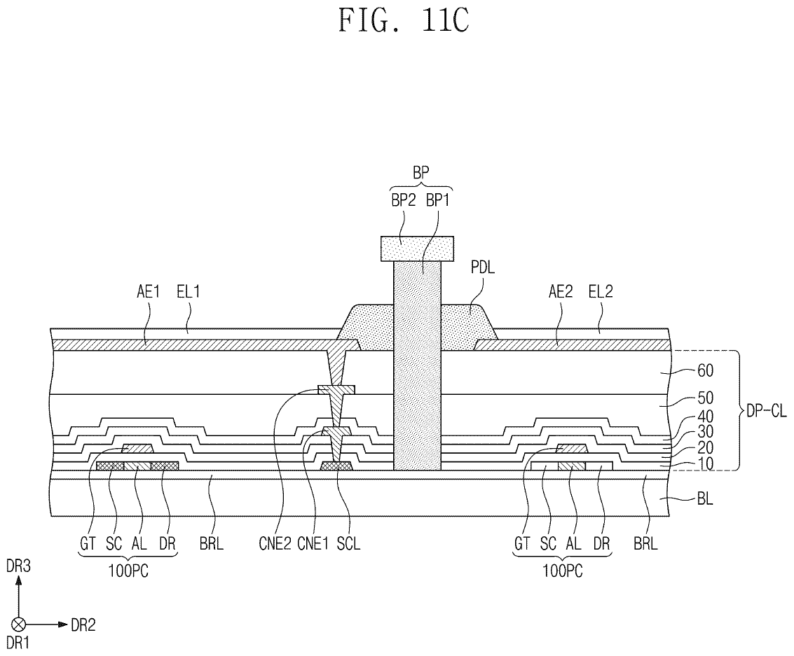

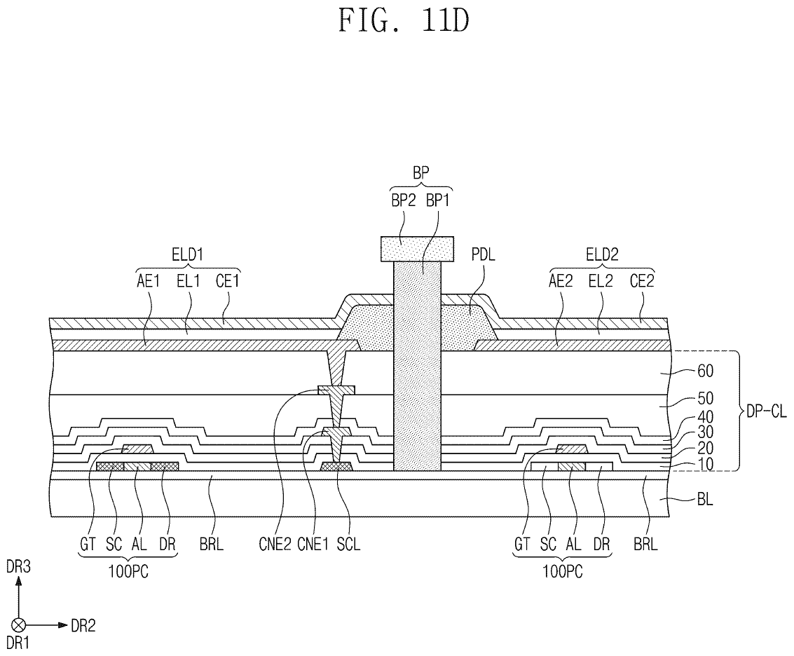

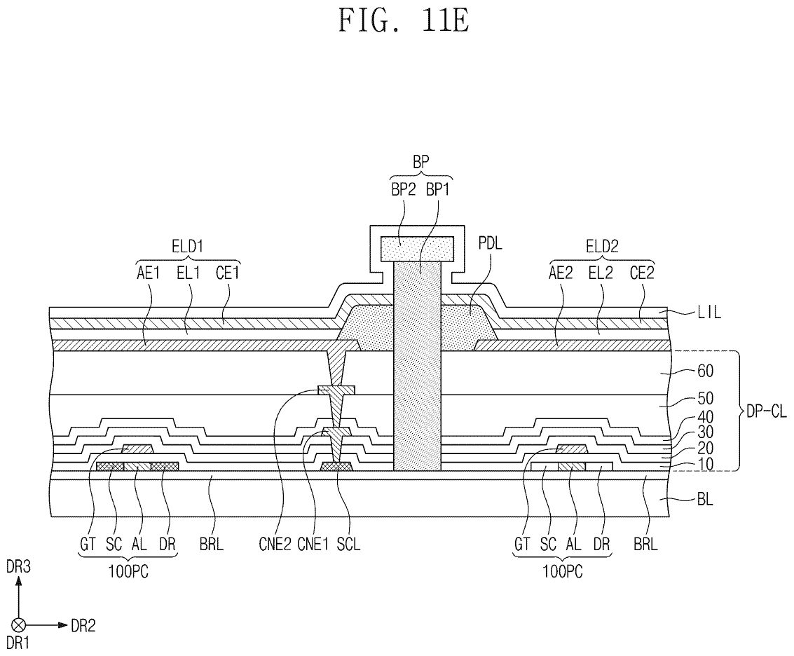

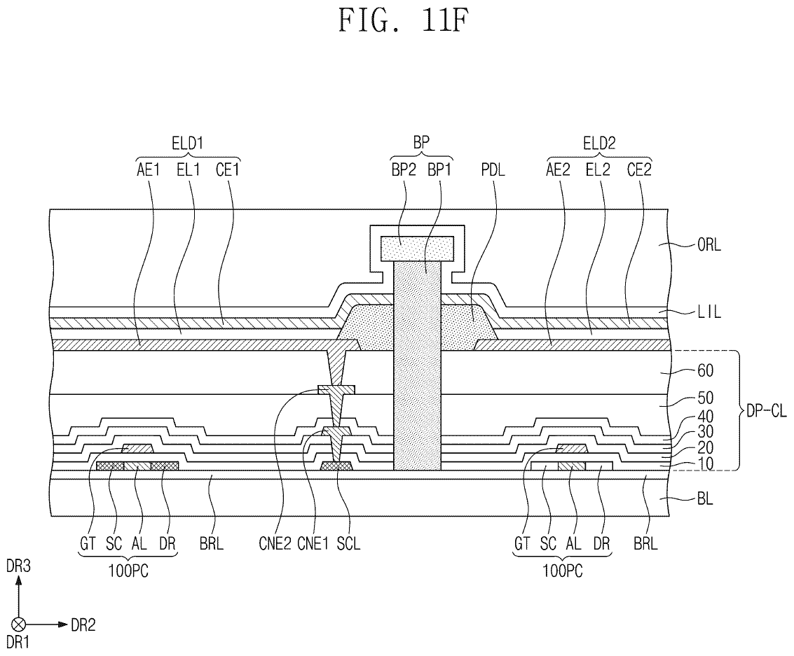

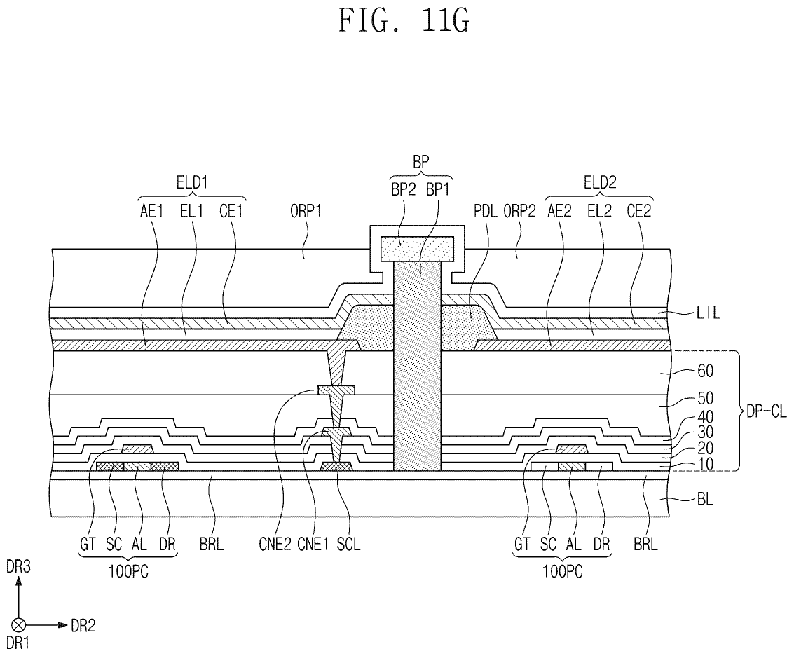

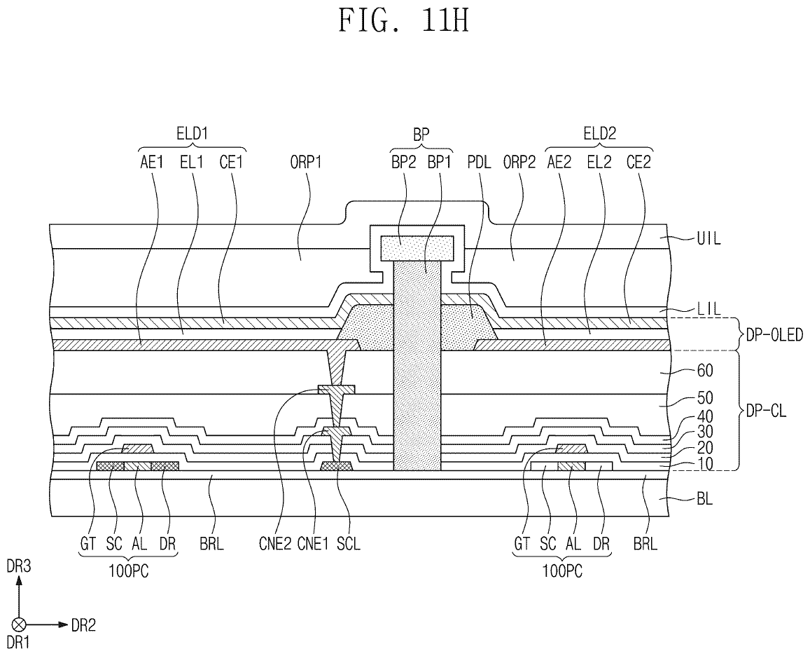

FIGS. 11A-11H are sectional views illustrating a manufacturing method of a display panel according to one or more embodiments of the present disclosure. In describing FIGS. 11A-11H, components identical or similar to the components described with reference to FIGS. 1-10 will be assigned with identical or similar reference numerals, and repetitive descriptions will be omitted.

Referring to FIG. 11A, the circuit element layer DP-CL is formed on the base layer BL. A process of forming a semiconductor layer and making the semiconductor layer subject to patterning and a process of forming a metal layer and making the metal layer subject to patterning are performed. A process of forming insulating layers is performed. These processes may be performed by various well-known methods.

Thereafter, first electrodes AE1 and AE2 are formed on the sixth insulating layer 60. After an electrode layer is formed, the first electrodes AE1 and AE2 are patterned. The patterning process is performed through a photolithography process. Thereafter, the pixel defining layer PDL is formed. According to one or more embodiments, after an organic layer is formed, the light emitting opening EOP may be formed through an exposure process and a developing process. According to one or more embodiments, after an inorganic layer is formed, the light emitting opening EOP may be formed through a photolithography process. A plurality of emissive layers EL1 and EL2 may be formed on the first electrodes AE1 and AE2.

The opening OP that passes through the pixel defining layer PDL and the intermediate insulating layers 10 to 60 is formed. The process of forming the opening OP may be concurrently (e.g., simultaneously) performed together with the process of forming the light emitting opening EOP. According to one or more embodiments, the process of forming the opening OP may include two steps. After a partial area of the opening OP is formed at the same time that the light emitting opening EOP is formed, the area of the opening OP that passes through the intermediate insulating layers 10 to 60 may be formed through an additional process.

Referring to FIG. 11B, a barrier pattern layer may be formed on the first electrodes AE1 and AE2 and the pixel defining layer PDL. The barrier pattern layer may include a first metal layer ML1 and a second metal layer ML2. After the first metal layer ML1 is formed through a deposition process, the second metal layer ML2 may be continuously formed. The first metal layer ML1 may fill the opening OP. The first metal layer ML1 and the second metal layer ML2 may have different etch rates.

As illustrated in FIG. 11C, the barrier pattern BP is formed by etching the first metal layer ML1 and the second metal layer ML2. The first metal layer ML1 inserted into the opening OP may have a higher etch rate than the second metal layer ML2. The first metal layer ML1 is etched more than the second metal layer ML2, and the second metal portion BP2 having a greater width than the first metal portion BP1 forms a tip structure.

Unlike that illustrated in FIG. 11C, the portion of the first metal portion BP1 inserted into the opening OP and the portion of the first metal portion BP1 that protrudes above the pixel defining layer PDL may have different widths depending on the width of the opening OP and the etch rate of the first metal layer ML1. Although an example of forming the barrier pattern BP using two types of metals is illustrated in the drawing, the manufacturing method may be common even though the barrier pattern BP is formed using one type of metal or three or more types of metals, and the shape of the formed structure is not limited to that illustrated in the drawing and may be differently formed depending on the etch rates of the metals and the width of the opening.

Thereafter, as illustrated in FIG. 11D, second electrodes CE1 and CE2 are formed.

Referring to FIG. 11D, the step of forming the second electrode CE may include a process of depositing a metal. For example, the step of forming the second electrode CE may include a step of sputtering a metal.

The second electrodes CE1 and CE2 may be separated from each other by the barrier pattern BP. Accordingly, the second electrodes CE1 and CE2 may be separately deposited on the plurality of emissive layers EL1 and EL2 by the barrier pattern BP. In one or more embodiments, the second electrode CE may also be deposited on the barrier pattern BP.

Thereafter, the thin film encapsulation layer TFE may be formed on the second electrodes CE1 and CE2.

Referring to FIG. 11E, the first inorganic encapsulation layer LIL may be formed. The first inorganic encapsulation layer LIL may be formed by depositing an inorganic material. In one or more embodiments, the first inorganic encapsulation layer LIL may be formed through a chemical vapor deposition (CVD) process. The first inorganic encapsulation layer LIL may be deposited to cover the second electrode CE and make direct contact with the side surface and the upper portion of the barrier pattern BP.

FIGS. 11F and 11G may include a step of forming the organic pattern ORP.

Referring to FIG. 11F, an organic layer ORL may be formed on the first inorganic encapsulation layer LIL. The organic layer ORL may be stacked on the first inorganic encapsulation layer LIL. The organic layer ORL may be formed by an ink-jet method and/or a deposition method, but is not limited thereto.

Referring to FIG. 11G, organic patterns ORP1 and ORP2 may be formed by etching the organic layer ORL. The organic patterns ORP1 and ORP2 may be formed to correspond to light emitting elements ELD1 and ELD2. The etch rate is adjusted such that the upper surface of the organic layer is lower than the barrier pattern BP. The organic layer may be divided into the organic patterns ORP1 and ORP2 by the barrier pattern BP. The separation distance may correspond to the width of the barrier pattern BP.

Thereafter, referring to FIG. 11H, the second inorganic encapsulation layer UIL is formed to cover the organic patterns ORP1 and ORP2. The second inorganic encapsulation layer UIL may be deposited on the first inorganic encapsulation layer LIL and the organic patterns ORP1 and ORP2. The method of forming the second inorganic encapsulation layer UIL is the same as the method of forming the first inorganic encapsulation layer LIL, and therefore description thereof will be omitted. The second inorganic encapsulation layer UIL may cover the organic patterns ORP1 and ORP2 and the upper portion of the barrier pattern BP and may seal the interior of the display panel DP.

The display panel DP including the base layer BL, the circuit element layer DP-CL, the display element layer DP-OLED, the barrier pattern BP, and the thin film encapsulation layer TFE may be formed according to the steps illustrated in FIGS. 11A-11H.

As described above, the thin film encapsulation layer may have the stack structure of the inorganic layer, the organic layer, and the inorganic layer in the areas corresponding to the light emitting elements and may have the stack structure of the inorganic layers in the other areas. Accordingly, the thin film encapsulation layer may maintain a sealing effect thereof and may decrease the thickness to improve flexibility.

Damage to the light emitting elements may be prevented by adding the structure that seals the inorganic layers of the thin film encapsulation layer and the light emitting elements.

While the present disclosure has been described with reference to embodiments thereof, it will be apparent to those of ordinary skill in the art that various changes and modifications may be made thereto without departing from the spirit and scope of the present disclosure as set forth in the following claims and their equivalents.

What is claimed is:

1. A display panel comprising:
a base layer;
a circuit element layer comprising at least one inorganic layer on the base layer, at least one intermediate insulating layer on the at least one inorganic layer, and a transistor;
a light emitting element comprising a first electrode electrically connected to the transistor, an emissive layer, and a second electrode on the emissive layer;
a pixel defining layer on the circuit element layer and defining a light emitting opening exposing the first electrode;
a barrier pattern including one portion that protrudes above the pixel defining layer, and contacting the at least one inorganic layer through an opening passing through the at least one intermediate insulating layer and the pixel defining layer; and
a thin film encapsulation layer comprising a first inorganic encapsulation layer contacting the barrier pattern and overlapping the light emitting element, a second inorganic encapsulation layer, and an organic pattern between the first inorganic encapsulation layer and the second inorganic encapsulation layer and overlapping the light emitting opening.

2. The display panel of claim 1, wherein the display panel includes an emissive area corresponding to the light emitting opening and a non-emissive area corresponding to the pixel defining layer, and
wherein the first inorganic encapsulation layer and the second inorganic encapsulation layer are in contact with each other in the non-emissive area.

3. The display panel of claim 2, wherein an area where the first inorganic encapsulation layer and the second inorganic encapsulation layer are in contact with each other is located on the barrier pattern.

4. The display panel of claim 1, wherein the one portion of the barrier pattern protruding above the pixel defining layer is in contact with the first inorganic encapsulation layer.

5. The display panel of claim 1, wherein the light emitting element comprises a first light emitting element and a second light emitting element, and
wherein a second electrode of the first light emitting element and a second electrode of the second light emitting element are separated from each other by the barrier pattern.

6. The display panel of claim 1, wherein the barrier pattern comprises a first metal portion inserted into the opening and a second metal portion protruding from the pixel defining layer, and
wherein the second metal portion has a greater width than the first metal portion and protrudes from the first metal portion on a cross-section.

7. The display panel of claim 6, wherein the first metal portion and the second metal portion have different etch rates.

8. The display panel of claim 6, wherein the second metal portion comprises:
a central portion configured to overlap the first metal portion in a thickness direction of the display panel;
a first side portion configured so as not to overlap the first metal portion in the thickness direction of the display panel; and
a second side portion configured so as not to overlap the first metal portion in the thickness direction of the display panel, and
wherein the central portion is between the first side portion and the second side portion.

9. The display panel of claim 2, wherein the display panel includes a display area including the emissive area and the non-emissive area, and a non-display area outside the display area, and
wherein the first inorganic encapsulation layer and the second inorganic encapsulation layer are in contact with each other in the non-display area.

10. The display panel of claim 1, wherein the barrier pattern has a closed-loop shape surrounding the light emitting element on a plane.

11. The display panel of claim 1, wherein the light emitting element comprises a plurality of light emitting elements, and
wherein the barrier pattern surrounds the plurality of light emitting elements in a closed-loop shape on a plane.

12. The display panel of claim 9, wherein the display area includes a first display area and a second display area,
wherein a plurality of light emitting elements are in each of the first display area and the second display area,
wherein the barrier pattern comprises a first barrier pattern and a second barrier pattern, and
wherein the first barrier pattern surrounds the first display area, and the second barrier pattern surrounds the second display area.

13. The display panel of claim 10, wherein the barrier pattern having the closed-loop shape blocks infiltration of oxygen and moisture into an emissive area corresponding to the light emitting opening.

14. The display panel of claim 1, wherein the transistor comprises a semiconductor pattern and a gate electrode over the semiconductor pattern,
wherein the at least one inorganic layer comprises a barrier layer located between the semiconductor pattern and the base layer, the barrier layer comprising silicon nitride, and
wherein the barrier pattern is in contact with the barrier layer.

15. The display panel of claim 14, wherein the at least one inorganic layer further comprises one or more intermediate inorganic layers on the barrier layer,
wherein an intermediate inorganic layer from among the one or more intermediate inorganic layers is located between the semiconductor pattern and the gate electrode, and another one of the intermediate inorganic layers is on the gate electrode, and
wherein the opening passes through the intermediate inorganic layers.

16. The display panel of claim 1, wherein the light emitting element comprises a first light emitting element and a second light emitting element,
wherein the organic pattern comprises a first organic pattern overlapping the first light emitting element and a second organic pattern overlapping the second light emitting element, and
wherein the first organic pattern and the second organic pattern are spaced from each other.

17. The display panel of claim 16, wherein the barrier pattern is located between the first organic pattern and the second organic pattern, and
wherein the first inorganic encapsulation layer and the second inorganic encapsulation layer are in contact with each other on the barrier pattern.

18. A display panel comprising:
a base layer;
a circuit element layer comprising a semiconductor pattern over the base layer, a barrier layer between the base layer and the semiconductor pattern, at least one intermediate insulating layer on the barrier layer, and a transistor;
a light emitting element comprising a first electrode electrically connected to the transistor, an emissive layer, and a second electrode on the emissive layer;
a pixel defining layer on the circuit element layer, the pixel defining layer including a light emitting opening defined therein to expose the first electrode; and
a thin film encapsulation layer comprising a first inorganic encapsulation layer in contact with the pixel defining layer and covering the light emitting element, a second inorganic encapsulation layer, and an organic pattern between the first inorganic encapsulation layer and the second inorganic encapsulation layer and overlapping the light emitting opening,
wherein the thin film encapsulation layer includes a first area and a second area on a plane, wherein the first inorganic encapsulation layer and the second inorganic encapsulation layer are in contact with each other in the first area, and the organic pattern is in the second area

19. The display panel of claim 18, further comprising:
a barrier pattern comprising one portion that protrudes above the pixel defining layer and is in contact with the first inorganic encapsulation layer, the barrier pattern contacting at least one inorganic layer through an opening passing through the at least one intermediate insulating layer and the pixel defining layer,
wherein the first area is located on the barrier pattern,
wherein the barrier pattern has a closed-loop shape surrounding the light emitting element on a plane,
wherein the barrier pattern comprises a first metal portion inserted into the opening and a second metal portion protruding from the pixel defining layer,
wherein the second metal portion has a width that is greater than a width of the first metal portion and protrudes from the first metal portion on a plane, and
wherein the barrier pattern has a T-shape on a cross-section.

20. An electronic device comprising:
a display device comprising a display panel; and
a processor configured to control the display device,
wherein the display panel comprises:
a base layer;
a circuit element layer comprising at least one inorganic layer on the base layer and at least one intermediate insulating layer on the at least one inorganic layer;
a light emitting element comprising a first electrode, an emissive layer, and a second electrode on the emissive layer;
a pixel defining layer on the circuit element layer, the pixel defining layer including a light emitting opening exposing the first electrode;
a barrier pattern comprising one portion that protrudes above the pixel defining layer, and contacting the at least one inorganic layer through an opening passing through the at least one intermediate insulating layer and the pixel defining layer; and
a thin film encapsulation layer comprising a first inorganic encapsulation layer contacting the barrier pattern and overlapping the light emitting element, a second inorganic encapsulation layer, and an organic pattern between the first inorganic encapsulation layer and the second inorganic encapsulation layer and overlapping the light emitting opening.
